(19) United States
(12) Patent Application Publication
(10) Pub. No.: US 2023/0336157 A1
(43) Pub. Date: Oct. 19, 2023

(54) MEMS DEVICE AND FABRICATION METHOD THEREOF

(71) Applicant: Ningbo Semiconductor International Corporation, Ningbo (CN)

(72) Inventors: Herb He HUANG, Ningbo (CN); Hailong LUO, Ningbo (CN); Wei LI, Ningbo (CN)

(21) Appl. No.: 18/211,049

(22) Filed: Jun. 16, 2023

Related U.S. Application Data
(63) Continuation of application No. PCT/CN2022/077173, filed on Feb. 22, 2022.

(30) Foreign Application Priority Data
Feb. 26, 2021 (CN) 202110218118.1

(51) Int. Cl. H03H 9/64; H03H 3/08; H03H 9/25

(52) U.S. Cl. CPC H03H 9/64; H03H 3/08; H03H 9/25

(57) ABSTRACT

A microelectromechanical systems (MEMS) device includes: a surface acoustic wave (SAW) filter including an interdigital transducer; a first structural layer disposed over the SAW filter; and a bulk acoustic wave (BAW) filter disposed over the first structural layer. The BAW filter includes a supporting substrate, an acoustic reflective structure disposed over the supporting substrate, and a piezoelectric stack structure disposed over the acoustic reflective structure. The piezoelectric stack structure includes a first electrode, a piezoelectric layer, and a second electrode. The first structural layer includes a first cavity covered by an effective resonance region of the piezoelectric stack structure and the interdigital transducer of the SAW filter.

### CROSS-REFERENCE TO RELATED APPLICATION

This application is a continuation application of PCT Patent Application No. PCT/CN2022/077173, filed on Feb. 22, 2022, which claims priority to Chinese Patent Application No. 202110218118.1, filed on Feb. 26, 2021, the entirety of all of which is incorporated herein by reference.

### TECHNICAL FIELD

The present disclosure relates to the technical field of microelectromechanical systems (MEMS) device and, more particularly, to a MEMS device and a fabrication method thereof.

### BACKGROUND

Microelectromechanical systems (MEMS) and integrated circuit (IC) are currently two most important development areas of the semiconductor industry. Driven by the global technology development, integration of M EMS and IC has become an inevitable trend. The integration includes three methods, namely, monolithic integration, semi-hybrid (bonding) integration, and hybrid integration. The monolithic integration refers to fabricating a MEMS structure and a complementary metal-oxide semiconductor (CMOS) structure on a same chip. The hybrid integration refers to fabricating the MEMS structure and the CMOS structure on separate dies and packaging them together into one device in which the MEMS bare chip with bumps is flipped and is soldered or wire-bonded to connect to the IC chip to form a system-in-package (SIP). The semi-hybrid integration refers to using a three-dimensional integration technology to three-dimensionally integrate the MEMS structure and the CMOS structure. The monolithic integration is an important development direction of the integration technology of the MEMS and IC, and provides many advantages for radio frequency (RF) thin film bulk acoustic wave (BAW) filters. Firstly, a processing circuit is close to a microstructure such that detected signals and transmitted signal are highly accurate. Secondly, the integrated system is small in volume and low in power consumption. Thirdly, the number of components and the number of package pins are reduced, resulting in higher reliability.

The existing RF BAW filter fabrication technology often integrates filters, drivers, and processing circuits together into one SIP. As requirements for the RF system performance are getting more stringent, multiple filters in different frequency bands need to be fabricated in one single wafer. Because of fabrication process and device characteristics of the BAW filter, it is difficult to fabricate multiple filters in different frequency bands in one single wafer. When the filters are fabricated, the fabrication process thereof is extremely complex. However, the BAW filter has many advantages, such as low insertion loss and high isolation. In certain applications, the BAW filter must be used.

Therefore, current MEMS devices have the technical problem of single frequency band restriction, low integration density, and complex fabrication process, which cannot meet the needs of high-performance RF systems.

### SUMMARY

One aspect of the present disclosure provides a microelectromechanical systems (MEMS) device. The MEMS device includes a surface acoustic wave (SAW) filter including an interdigital transducer; a first structural layer disposed over the SAW filter; and a bulk acoustic wave (BAW) filter disposed over the first structural layer. The BAW filter includes a supporting substrate, an acoustic reflective structure disposed on a surface of the supporting substrate, and a piezoelectric stack structure disposed over the acoustic reflective structure. The piezoelectric stack structure includes a first electrode, a piezoelectric layer, and a second electrode. The first structural layer includes a first cavity covered by an effective resonance region of the piezoelectric stack structure and the interdigital transducer of the SAW filter.

Another aspect of the present disclosure provides a method for fabricating a microelectromechanical systems (MEMS) device. The fabrication method includes: providing a surface acoustic wave (SAW) filter including an interdigital transducer; providing a bulk acoustic wave (BAW) filter including a supporting substrate, a support layer disposed on a surface of the supporting substrate, and a piezoelectric stack structure configured to enclose a second cavity with the support substrate and the support layer; and bonding the BAW filter to the SAW filter through a first structural layer to form a first cavity with the SAW filter. An effective resonance region of the piezoelectric stack structure and the interdigital transducer of the SAW filter together cover the first cavity.

### BRIEF DESCRIPTION OF THE DRAWINGS

To more clearly illustrate the technical solution of the present disclosure, the accompanying drawings used in the description of the disclosed embodiments are briefly described below. The drawings described below are merely some embodiments of the present disclosure. Other drawings may be derived from such drawings by a person with ordinary skill in the art without creative efforts and may be encompassed in the present disclosure.

FIG. 1 is a structural schematic diagram of an exemplary MEMS device according to some embodiments of the present disclosure;

FIGS. 2-6 are structural schematic diagrams corresponding to different steps in an exemplary MEMS device fabrication method according to some embodiments of the present disclosure;

FIGS. 7-10 are structural schematic diagrams corresponding to different steps in another exemplary MEMS device fabrication method according to some embodiments of the present disclosure; and

FIGS. 11-12 are structural schematic diagrams corresponding to different steps in another exemplary MEMS device fabrication method according to some embodiments of the present disclosure.

### DETAILED DESCRIPTION OF THE EMBODIMENTS

The substrate material of a surface acoustic wave (SAW) filter may be lithium niobate or lithium tantalate. The material properties and thermal expansion coefficient thereof are different from ordinary substrates (e.g., silicon substrates). The substrate of the SAW filter is easy to break, and is not easy to be compatible with a commonly used silicon wafer process. Thus, it is not easy to integrate wafer-level processes of the SAW filter and the BAW filter together in the existing technology. In addition, due to the fabrication process and device characteristics of the BAW filter, it is difficult to form the BAW filter with multiple frequency bands on a single wafer even if it can be done at all. The complexity of the fabrication process is very high. But the BAW filter does have significant advantages, such as low insertion loss and high isolation. In some applications, the BAW filter is a must. On the other hand, the fabrication process and device characteristics of the SAW filter make it easy to fabricate a filter with multiple frequency bands on one single wafer. It is more cost-effective to use the SAW filter. Thus, how to bond the SAW filter and the BAW filter together to solve the problems of single frequency band limitation, low integration density, and cumbersome fabrication process of the current MEMS devices is an urgent problem to be solved.

The MEMS device and the fabrication method thereof of the present disclosure will be further described in detail below with reference to the accompanying drawings and various embodiments. In order to make the objectives, technical solutions, and advantages of the present disclosure clearer, the present disclosure will be further described in detail below with reference to the accompanying drawings. Obviously, the described embodiments are only some of the embodiments of the present disclosure, not all of the embodiments. Based on the embodiments of the present disclosure, all other embodiments obtained by those of ordinary skill in the art without creative efforts shall fall within the scope of the present disclosure. The drawings are all in very simplified form and use imprecise scales, and are merely intended to facilitate and clearly assist the purpose of illustrating the embodiments of the present disclosure.

The terms “first”, “second”, etc. in the specification and claims are used to distinguish between similar elements and not necessarily to describe a specific order or chronological order. It should be understood that the terms so used are interchangeable under appropriate circumstances, for example, to enable the embodiments of the present disclosure described herein to be operated in other sequences than described or illustrated herein. Similarly, if a method described herein includes a series of steps, the order in which these steps are presented is not necessarily the only order in which these steps can be performed, and some described steps may be omitted and/or some additional steps not described herein can be added. If the components in a certain drawing are the same as those in other drawings, although these components can be easily identified in all the drawings, in order to make the description of the drawings clearer, the specification will not mark reference numerals for all the same components in each figure.

### Embodiment 1

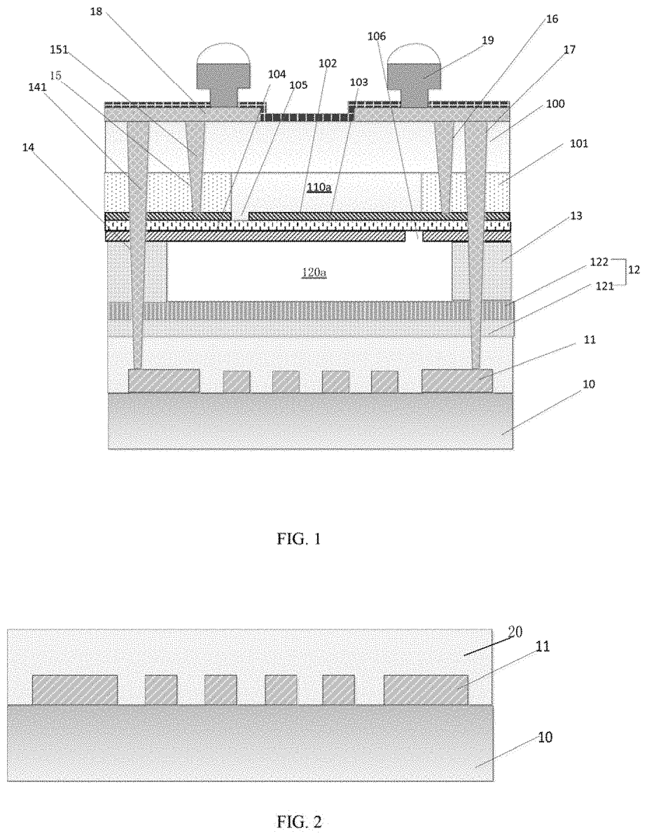

The present disclosure provides a MEMS device. FIG. 1 is a structural schematic diagram of an exemplary MEMS device according to some embodiments of the present disclosure. As shown in FIG. 1, the MEMS device includes: a SAW filter including an interdigital transducer 11, a first structural layer 13 disposed over the SAW filter, and a BAW filter disposed over the first structural layer 13. The BAW filter includes a supporting substrate 100, an acoustic reflective structure (not shown) disposed on the supporting substrate 100, and a piezoelectric stack structure disposed on the acoustic reflective layer. The piezoelectric stack structure includes a first electrode 102, a piezoelectric layer 103, and a second electrode 104 stacked sequentially. The first structural layer 13 includes a first cavity 120a. An effective resonance region of the piezoelectric stack structure and the interdigital transducer 11 of the SAW filter cover the first cavity 120a.

The BAW filter may also be a thin-film BAW resonator or a solid-state assembled resonator. When the acoustic reflective structure includes a cavity, the BAW filter may be the thin-film BAW resonator. When the acoustic reflective structure includes a Bragg reflective layer, the BAW filter may be the solid-state assembled resonator. For illustration purpose, the thin-film BAW filter will be used when describing the present disclosure.

The first cavity 120a may be formed by etching the first structural layer 13 using an etching process. However, the present disclosure is not limited thereto. A bonding interface is disposed between the first structural layer 13 and the BAW filter. The first structural layer 13 is bonded to the BAW filter through the bonding interface. Through a bonding process, the BAW filter is bonded to the first structural layer 13 disposed on the SAW filter to form the first cavity 120a with the SAW filter. Vertical integration of the BAW filter and the SAW filter in a device fabrication stage eliminates a back-end system-in-package (SIP) process, simplifies the fabrication process, reduces the packaging volume of an entire system, and substantially improves integration level. The bonding process may include metal bonding, covalent bonding, adhesive bonding, or fusion bonding. The first structural layer and the filter are bonded together through a bonding layer. The material of the bonding layer includes a photolithographic organic curable film, silicon oxide, silicon nitride, silicon oxynitride, silicon carbonitride, ethyl silicate, or metal. In some other embodiments, the first structural layer 13 may also be disposed on the BAW filter. A bonding interface is disposed between the first structural layer 13 and the SAW filter. The first structural layer 13 is bonded to the SAW filter through the bonding interface, thereby achieving a bonding connection between the BAW filter and the SAW filter.

In some embodiments, a shape of a bottom surface of the first cavity 120a is a rectangle. In some other embodiments, the shape of the bottom surface of the first cavity 120a may also be a circle, an ellipse, or a polygon other than a rectangle, such as a pentagon, a hexagon, etc.

It should be noted that, through the first structural layer 13 of the first cavity 120a provided between the SAW filter and the BAW filter, the effective resonance region of the piezoelectric stack structure and the interdigital transducers 11 of the SAW filter together cover the first cavity 120a, which achieves the vertical integration, reduces the packaging volume of the entire system, achieving the miniaturization, and substantially improves the integration level. The structure of the MEMS device provided by the present disclosure not only retains the advantages of high frequency and low insertion loss of the BAW filter, but also reduces a fabrication process cost to satisfy the requirement of multiple frequency bands. Disposing the effective resonance region of the piezoelectric stack structure in the first cavity 120a effectively improves a quality factor of the BAW filter.

The effective resonance region of the piezoelectric stack structure and the interdigital transducer 11 of the SAW filter together cover the first cavity 120a. For example, the effective resonance region and the interdigital transducer 11 face toward the first cavity 120a to cover the first cavity 120a, respectively. Alternatively, at least one of the effective resonance region or the interdigital transducer 11 protrudes into the first cavity 120a.

In some embodiments, the first cavity 120a penetrates through the first structural layer 13. The first structural layer 13 may be a photolithographically curable organic film or an oxide layer. In some embodiments, the first structural layer 13 is the photolithographically curable organic film, which has one-sided or double-sided adhesives. The first structural layer 13 may be made of a film-like material or a liquid material, and may be photoetched and cured. The first structural layer 13 has a relatively small elastic modulus, capable of relieving a bonding stress between the SAW filter and the BAW filter. The bonding between the SAW filter and the BAW filter is highly reliable. The first structural layer 13 may be photolithographically etched to obtain the first cavity 120a, which causes less damage to the surface of acoustic wave filters, and further improves the quality factor of the device. The first structural layer 13 have a thickness ranging from 5 μm to 50 μm. The subsequent bonding of the SAW wave filter and the BAW filter needs to reach a certain thickness, and a first isolation groove subsequently formed on the first structural layer 13 also needs to have a certain depth. Thus, in some embodiments, by limiting the thickness of the first structural layer 13 to the range between 5 μm and 50 μm, a bonding condition of bonding the SAW filter and the subsequent BAW filter can be met and cost savings can be achieved. In some other embodiments, the thickness of the first structural layer 13 may also be thicker or thinner than the above-described range.

In some embodiments, a passivation layer 12 is arranged between the first structural layer 13 and the SAW filter, and by disposing the passivation layer 12 on the SAW filter, the SAW filter can be protected, and a structural strength and device performance of the SAW filter can be improved. The passivation layer 12 includes an oxide layer 121 and an etch stop layer 122. The oxide layer 121 is located on an upper surface of the SAW filter, and the etch stop layer 122 is located on the oxide layer 121. The material of the oxide layer 121 may include at least one of insulating materials such as silicon oxide, silicon oxynitride, silicon nitride, etc. By disposing the oxide layer 121 on the surface of the SAW filter, the SAW filter is protected from dust and moisture. The etch stop layer 122 is provided on the oxide layer 121. The material of the etch stop layer 122 includes but not limited to silicon nitride and silicon oxynitride. In some embodiments, the etch stop layer 122 is made of silicon nitride. Silicon nitride has a high density and a high strength, which improves the waterproof and anti-corrosion effect of the SAW filter.

In addition, on one hand, the etch stop layer 122 may be used to increase structural stability of the fabricated filter. On the other hand, the etch stop layer 122 has a lower etching rate compared with the photolithographically curable organic film. Over-etching may be prevented during a process of etching the photolithographically curable organic film to form the first cavity 120a. The surface of the underlying structure may be protected from damage, thereby improving device performance and reliability.

In some other embodiments, the passivation layer 12 may only include one of the oxide layer 121 and the etch stop layer 122. The passivation layer 12 may also have other structures, which are not limited here.

In some embodiments, the SAW filter further includes a support substrate 10 and a dielectric layer 20 disposed on the support substrate 10.

It should be noted that the SAW filter is formed by evaporating a layer of metal film on a material substrate with piezoelectric effect, and then performing a photolithography process to form a pair of interdigitated electrodes at both ends. The SAW filter has advantages of high operating efficiency, wide pass band frequency, excellent frequency selection characteristics, small size, and light weight, and may be fabricated using a same production process as integrated circuits. The SAW filter is simple to fabricate and low in cost.

The support substrate 10 has a first surface and a second surface arranged opposite to each other. The dielectric layer 20 is disposed on the first surface of the support substrate 10. The interdigital transducer 11 is located in the dielectric layer 20 on the first surface of the support substrate 10. The interdigital transducer 11 includes a transmitting transducer and a receiving transducer. When a signal voltage is applied to the transmitting transducer, an electric field is formed between input interdigital electrodes to cause the piezoelectric material to mechanically vibrate and propagate in a form of ultrasonic waves to both sides. The receiving transducer converts the mechanical vibration into an electrical signal, which is outputted by output interdigitated electrodes.

In some embodiments, the BAW filter is located over the first structural layer 13. The BAW filter includes a supporting substrate 100, a support layer 101 disposed on a surface of the supporting substrate 100, and a piezoelectric stack structure configure to enclose a second cavity 110a together with the supporting substrate 100 and the support layer 101.

Specifically, orthogonal projections of the first cavity 120a and the second cavity 110a on the piezoelectric stacked structure at least partially overlap, such that both the upper and lower sides of the effective resonance region of the piezoelectric stacked structure are exposed in the air, which further improves the quality factor of the BAW filter.

The supporting substrate 100 may be made of at least one of silicon (Si), germanium (Ge), silicon germanium (SiGe), silicon carbon (SiC), silicon germanium carbon (SiGeC), indium arsenide (InAs), gallium arsenide (GaAs), indium phosphide (InP), or other III/V compound semiconductors. The supporting substrate 100 may also include multilayer structures composed of the over-described semiconductors, etc. The supporting substrate 100 may also be an alumina ceramic substrate, or a quartz or glass substrate.

The support layer 101 is bonded to the supporting substrate 100 and forms the second cavity 110a with the piezoelectric stack structure, and the second cavity 110a exposes the supporting substrate 100. In some embodiments, the second cavity 110a is an annular closed cavity, and the second cavity 110a may be formed by etching the support layer 101 through an etching process. However, the present disclosure is not limited thereto. It should be noted that, the support layer 101 is combined with the supporting substrate 100 by a bonding process, and the bonding process includes: metal bonding, covalent bonding, adhesive bonding, or fusion bonding. In some embodiments, the support layer 101 and the supporting substrate 100 are bonded through a bonding layer, and the material of the bonding layer includes silicon oxide, silicon nitride, silicon oxynitride, silicon carbonitride, or ethyl silicate.

In some embodiments, a shape of a bottom surface of the second cavity 110a is rectangular. In some other embodiments, the shape of the bottom surface of the second cavity 110a on the first electrode 102 may also be circular, oval, or polygons other than rectangles, such as pentagons, hexagons, etc. The material of the support layer 101 may be any suitable dielectric material, including but not limited to one of silicon oxide, silicon nitride, silicon oxynitride, silicon carbonitride, and other materials. The materials of the support layer 101 and the bonding layer may be the same.

The piezoelectric stack structure is disposed over the second cavity 110a. The piezoelectric stack structure includes the first electrode 102, the piezoelectric layer 103, and the second electrode 104 arranged sequentially. The first electrode 102 is disposed on the support layer 101, the piezoelectric layer 103 is disposed on the first electrode 102, and the second electrode 104 is disposed on the piezoelectric layer 103.

In some embodiments, the piezoelectric layer 103 covers the second cavity 110a. It should be understood that covering the second cavity 110a refers to that the piezoelectric layer 103 is an entire film without being etched. However, it does not mean that the piezoelectric layer 103 completely covers the second cavity 110a to form a sealed cavity. Of course, the piezoelectric layer 103 may completely cover the second cavity 110a to form the sealed cavity. The fact that the piezoelectric layer 103 is not etched ensures a certain thickness of the piezoelectric stack structure, such that the BA W filter has a certain structural strength, and the yield of fabricating the BAW filter is improved.

In some embodiments, the etch stop layer is further disposed between the support layer 101 and the first electrode 102. The material of the etch stop layer includes but not limited to silicon nitride (Si3N4) and silicon oxynitride (SiON). On one hand, the etch stop layer may be used to increase the structural stability of the finished BAW resonator. On the other hand, the etch stop layer has a lower etching rate compared with the support layer 101, prevents over-etching during a process of forming the second cavity 110a, protects the surface of the first electrode 102 disposed thereunder from being damaged, and improves the device performance and reliability.

In some embodiments, the piezoelectric stack structure further includes a first groove 105 and a second groove 106 on its surface. The first groove 105 is disposed on a lower surface of the piezoelectric stack structure on a bottom side where the second cavity 110a is located, and penetrates through the first electrode 102. The second groove 106 is disposed on an upper surface of the piezoelectric stacked structure and penetrates through the second electrode 104. Two ends of the first groove 105 are arranged opposite to two ends of the second groove 106, such that two junctions of orthogonal projections of the first groove 105 and the second groove 106 on the supporting substrate 100 meet with each other or may be separated by a gap. In some embodiments, the orthogonal projections of the first groove 105 and the second groove 106 on the supporting substrate 100 are closed figures. The first electrode 102, the piezoelectric layer 103, and the second electrode 104 disposed over the first cavity 120a have an overlapping region in a direction perpendicular to the supporting substrate 100, which is located between the first groove 105 and the second groove 106. The overlapping region is the effective resonance region. The effective resonance region of the BAW filter is defined by the first groove 105 and the second groove 106, and the first groove 105 and the second groove 106 penetrate through the first electrode 102 and the second electrode 104, respectively. The piezoelectric layer 103 remains intact without being etched, which ensures the structural strength of the BAW filter and improves the yield of fabricating the BAW filter.

In some embodiments, the SAW filter is electrically connected to an external circuit through a first electrical connection structure 14 and a fourth electrical connection structure 17, and the BAW filter is electrically connected to another external circuit through a second electrical connection structure 15 and a third electrical connection structure 16. By forming the electrical connection structures with the BAW filter and the SAW filter to electrically connect to different external circuits respectively, mutual interferences of signals of the SAW filter and the BAW filter can be avoided, and the performance of the MEMS device can be improved.

The first electrical connection structure 14 includes a first interconnection hole (not shown) and a first conductive interconnection layer 141 disposed in the first interconnection hole. The first interconnection hole penetrates through from one side of the supporting substrate 100 and extends to the interdigital transducer 11 of the SAW filter. The second electrical connection structure 15 includes a second interconnection hole (not shown) and a second conductive interconnection layer 151 disposed in the second interconnection hole. The second interconnection hole penetrates through from one side of the supporting substrate 100 and extends to the first electrode 102 outside the effective resonance region of the piezoelectric stack structure. The supporting substrate 100 is provided with an interconnection line 18. The first conductive interconnection layer 141 includes a first plug, and the second conductive interconnection layer 151 includes a second plug. The first plug and the second plug are electrically connected to the interconnection line 18.

The interdigital transducer 11 includes interdigital electrodes disposed at an input end and an output end respectively. The first electrical connection structure is used to introduce an electrical signal to the input end of the interdigital transducer 11. When the electric signal is inputted to the input end of the interdigital transducer 11, under influence of an alternating electric field of the inputted electrical signal and due to a piezoelectric effect of a crystal, a mechanical vibration is excited on a substrate surface of the interdigital transducer 11 to form a surface acoustic wave. The electrical connection structure is used to connect the output end of the interdigital transducer 11. The surface acoustic wave formed at the input end propagates along the surface of the substrate to the interdigital electrode at the output end. Due to a pressure effect, the electric field changes due to the mechanical vibration and the electrical signal is outputted at the output end. The second electrical connection structure is used to introduce another electrical signal into the second electrode of the effective resonance region, and the third electrical connection structure is used to introduce another electrical signal into the first electrode of the effective resonance region. After the first electrode 102 and the second electrode 104 are energized, a pressure difference is generated on the upper and lower surfaces of the piezoelectric layer 103 to form a standing wave oscillation.

The specific structures of the first electrical connection structure 14 and the second electrical connection structure 15 are as follows. The first electrical connection structure 14 includes the first interconnect hole. The first interconnect hole penetrates from one side of the supporting substrate 100 and extends to the interdigital transducer 11 of the SAW filter. The first conductive interconnection layer 141 covers an inner surface of the first interconnection hole and is electrically connected to the interconnection line 18 on the surface of the supporting substrate 100. The second electrical connection structure 15 includes the second interconnection hole. The second interconnection hole penetrates from one side of the supporting substrate 100, extends to the first electrode 102 outside the effective resonance region of the piezoelectric stack structure, and exposes the first electrode 102. The second conductive interconnection layer 151 covers an inner surface of the second interconnection hole and is electrically connected to the interconnection line 18 on the surface of the supporting substrate 100.

It should be noted that the second electrical connection structure 15 is not directly electrically connected to the second electrode 104, but is connected to the first electrode 102 outside the effective resonance region, and is electrically connected to the second electrode 104 of the effective resonance region through a conductive interconnection structure (not shown). The third electrical connection structure 16 is electrically connected to the first electrode 102 inside the effective resonance region, and supplies power to the first electrode 102 inside the effective resonance region. It can be seen that the first electrical connection structure 14 and the fourth electrical connection structure 17 are consistent in structure, but are located at different positions. The second electrical connection structure 15 and the third electrical connection structure 16 are also consistent in structure, but are located at different positions. The descriptions about the third electrical connection structure 16 and the fourth electrical connection structure 17 are thus omitted herein.

In some embodiments, the MEMS device also includes an insulating layer covering the interconnection line 18 and the surface of the supporting substrate 100. A conductive bump 19 is disposed on the surface of the supporting substrate 100 and is electrically connected to the interconnection line 18.

### Embodiment 2

The present disclosure also provides a method of fabricating a MEMS device. The method includes the following processes.

At S01, a SAW filter is provided. The SAW filter includes an interdigital transducer.

At S02, a BAW filter is provided. The BAW filter includes a supporting substrate, a support layer disposed on a surface of the supporting substrate, and a piezoelectric stack structure configured to enclose a second cavity with the supporting substrate and the support layer.

At S03, the BAW filter is bonded to the SAW filter through a first structural layer, and forms a first cavity with the BAW filter.

At S04, an effective resonance region of the piezoelectric stack structure and the interdigital transducer of the SAW filter together cover the first cavity.

The sequence numbers of the processes do not represent a sequence of performing the processes.

FIGS. 2-12 are structural schematic diagrams corresponding to different steps in an exemplary MEMS device fabrication method according to some embodiments of the present disclosure. The method of fabricating the MEMS device is described in detail in the following with reference to FIGS. 2-12.

Referring to FIG. 2, the SAW filter is provided.

The process of forming the SAW filter includes: providing a support substrate 10; forming the interdigital transducer 11 on the support substrate 10; and forming a dielectric layer 20 on a first surface of the support substrate 10. The dielectric layer 20 covers the first surface of the support substrate 10 and the interdigital transducer 11. The support substrate 10 includes the first surface and a second surface. The interdigital transducer 11 is formed on the first surface of the support substrate 10.

For operation principle of the interdigital transducer 11, reference can be made to Embodiment 1, and the description thereof is omitted herein.

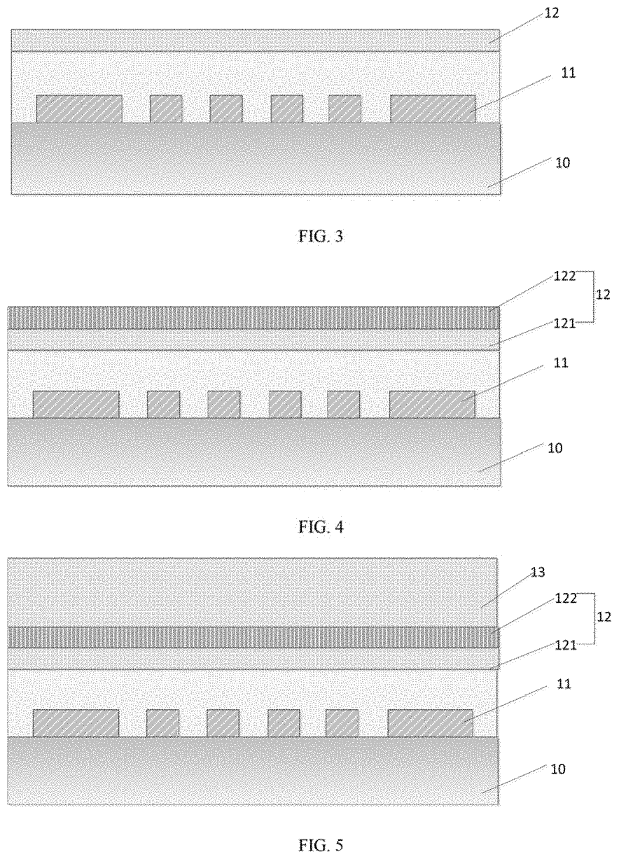

Referring to FIG. 3 and FIG. 4, a passivation layer 12 is formed on the SAW filter.

The process of forming the passivation layer 12 includes: forming an oxide layer 121 on the dielectric layer 20 as shown in FIG. 3; and forming an etch stop layer 122 on the oxide layer 121 as shown in FIG. 4. The etch stop layer 122 and the oxide layer 121 together form the passivation layer 12. For the material and function of the oxide layer 121, reference can be made to Embodiment 1, and the description thereof is omitted herein. For the material and function of the etch stop layer 122, reference can be made to Embodiment 1, and the description thereof is omitted herein.

Referring to FIG. 5, in some embodiments, a first structural layer 13 is formed on the passivation layer 12.

The first structural layer 13 may be a photolithographically curable organic film. The function of the photolithographically curable organic film is the same as that in Embodiment 1 over. In some other embodiments, the first structural layer 13 is not formed on the passivation layer 12, but may be formed on the piezoelectric stack structure of the BAW filter. For the specific formation process, reference can be made to FIGS. 7-10, the description thereof is omitted herein.

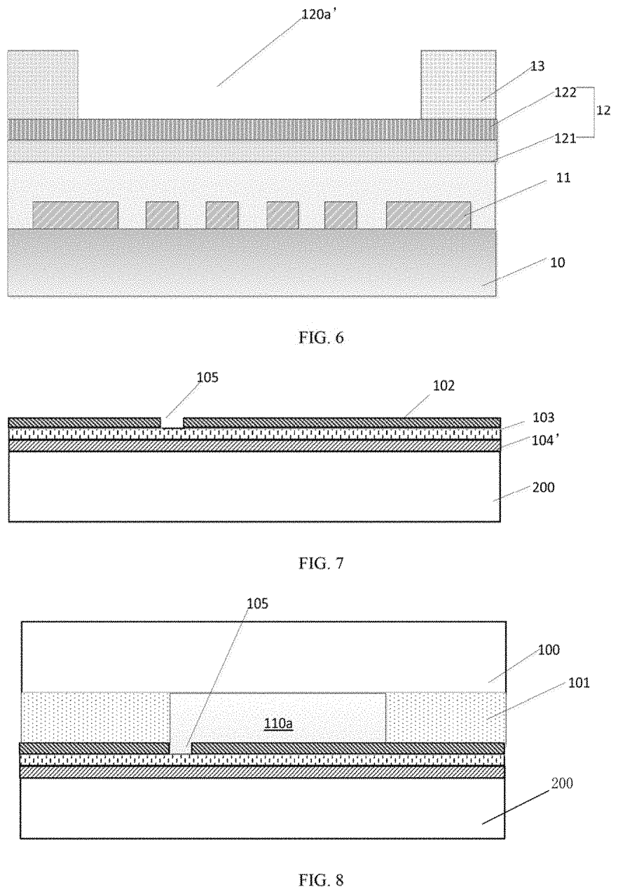

Referring to FIG. 6, the first structural layer 13 is etched to form a first isolation groove 120a′, such that the interdigital transducer 11 is arranged opposite to the first isolation groove 120a′.

Referring to FIGS. 7-9, the BAW filter is provided. The BAW filter includes: a supporting substrate, a support layer formed on a surface of the supporting substrate, and a piezoelectric stack structure configured to enclose a second cavity with the supporting substrate and the support layer. For the specific forming process of the BAW filter, reference can be made to FIGS. 7-9.

Referring to FIG. 7, a temporary substrate 200 is provided.

The temporary substrate 200 may be any suitable substrate well known to those skilled in the art, and may include at least one of silicon (Si), germanium (Ge), silicon germanium (SiGe), arsenide Indium (Ins), indium phosphide (InP), or other III/V compound semiconductors. The temporary substrate 200 may also include multilayer structures including the over-described semiconductors. For example, the temporary substrate 200 may be silicon-on-insulator (SOI), stacked silicon-on-insulator (SSOI), stacked silicon-germanium-on-insulator (S-SiGeOI), silicon germanium-on-insulator (SiGeOI), germanium-on-insulator (GeOI), or double-sided polished silicon (DSP) wafer. The temporary substrate 200 may also be an aluminum oxide ceramic substrate or a quartz or glass substrate. In some embodiments, the temporary substrate 200 is a P-type high-resistance single crystal silicon wafer with a <100> crystal orientation.

A second electrode layer 104′, a piezoelectric layer 103, and a first electrode 102 are sequentially formed on the temporary substrate 200. The material of the second electrode layer 104′ and the first electrode 102 may include any suitable conductive material or semiconductor material well known to those skilled in the art. The conductive material may be a metallic material with conductive properties. For example, the conductive material may be molybdenum (Mo), aluminum (Al), copper (Cu), tungsten (W), tantalum (Ta), platinum (Pt), ruthenium (Ru), rhodium (Rh), iridium (Ir), chromium (Cr), titanium (Ti), gold (Au), osmium (Os), rhenium (Re), palladium (Pd), and other metals or a stack of the over metals. The semiconductor material may include Si, Ge, SiGe, SiC, and SiGeC, etc. The second electrode layer 104′ and the first electrode 102 may be formed by physical vapor deposition or chemical vapor deposition methods such as magnetron sputtering and evaporation. The material of the piezoelectric layer 103 may be a piezoelectric material with a wurtzite crystal structure, such as aluminum nitride (AlN), zinc oxide (ZnO), lead zirconate titanate (PZT), lithium niobate (LiNbO3), quartz (Quartz), potassium niobate (KNbO3), lithium tantalum acid (LiTaO3), and a combination thereof. When the piezoelectric layer 103 includes aluminum nitride (AlN), the piezoelectric layer 103 may further include a rare earth metal such as at least one of scandium (Sc), erbium (Er), yttrium (Y), or lanthanum (La). In addition, when the piezoelectric layer 103 includes aluminum nitride (AlN), the piezoelectric layer 103 may further include a transition metal such as at least one of zirconium (Zr), titanium (Ti), manganese (Mn), or hafnium (Hf). The piezoelectric layer 103 may be deposited and formed by any suitable method known to those skilled in the art, such as chemical vapor deposition, physical vapor deposition, or atomic layer deposition. In some embodiments, the second electrode layer 104′ and the first electrode 102 are made of metal molybdenum (Mo), and the piezoelectric layer 103 is made of aluminum nitride (AlN).

In some embodiments, after the first electrode 102 is formed, the first electrode 102 is etched to form the first groove 105 penetrating through the first electrode 102. The first groove 105 is located in the subsequently formed first cavity 120a, and a sidewall of the first groove 105 may be inclined or vertical. In some embodiments, the sidewall of the first groove 105 forms a right angle with a plane where the piezoelectric layer 103 is located (a longitudinal rectangular-shaped cross-section of the first groove 105 along a film thickness direction). In some other embodiments, the sidewall of the first groove 105 forms an obtuse angle with the plane where the piezoelectric layer 103 is located. The orthogonal projection of the first groove 105 on the plane where the piezoelectric layer 103 is located is a half-ring or a polygon similar to a half-ring.

Referring to FIG. 8, the supporting substrate 100 includes the second cavity 110a formed on the piezoelectric layer. The supporting substrate 100 covers part of the first electrode, and the effective resonance region of the first electrode is located within the boundary of an area enclosed by the second cavity 110a.

The support layer 101 is also formed on the piezoelectric layer 103. The support layer 101 is bonded to the supporting substrate 100 and forms the second cavity 110a with the piezoelectric layer 103. The second cavity 110a exposes the supporting substrate 100. In some embodiments, the second cavity 110a is an annular closed cavity. The second cavity 110a may be formed by etching the support layer 101 through an etching process. However, the present disclosure is not limited thereto. It should be noted that the support layer 101 is combined with the supporting substrate 100 by a bonding process. The bonding process includes metal bonding, covalent bonding, adhesive bonding, or fusion bonding. In some embodiments, the support layer 101 and the supporting substrate 100 are bonded together through a bonding layer, and the material of the bonding layer may include silicon oxide, silicon nitride, silicon oxynitride, silicon carbonitride, or ethyl silicate.

In some embodiments, a shape of a bottom surface of the second cavity 110a is a rectangle. In some other embodiments, the shape of the bottom surface of the second cavity 110a on the first electrode 102 may also be circular, oval or polygons other than rectangles, such as pentagons, hexagons, etc. The material of the support layer 101 may be any suitable dielectric material, including but not limited to one of silicon oxide, silicon nitride, silicon oxynitride, silicon carbonitride, and other suitable materials. The material of the support layer 101 and the bonding layer may be the same.

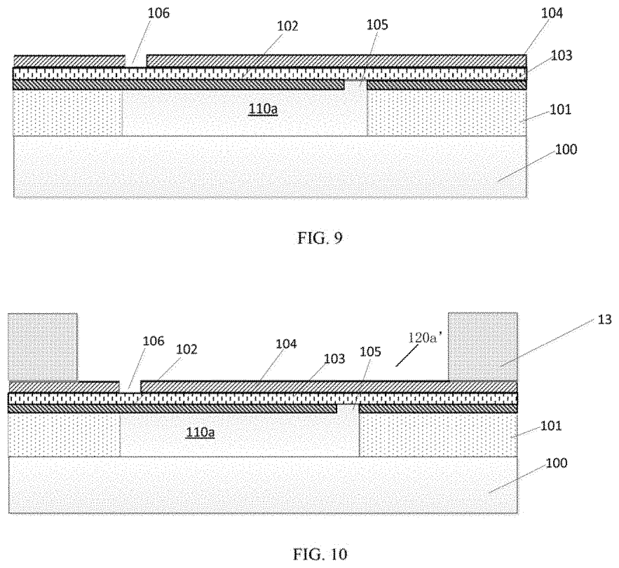

Referring to FIG. 9, the temporary substrate 200 is removed.

After the temporary substrate 200 is removed, a patterning process is performed on the second electrode layer 104′ to form the second electrode 104. The first electrode, the piezoelectric layer, and the second electrode together form the piezoelectric stack structure. The second groove 106 is formed on the second electrode 104 penetrating through the second electrode 104. The second groove 106 is formed on a side opposite to the first groove 105. In some embodiments, two junctions of orthogonal projections of the first groove 105 and the second groove 106 on the supporting substrate 100 meet with each other to form a closed irregular polygon. For description of the structure and formation method of the second groove 106, reference can be made to the description of the structure and formation method of the first groove 105. In some other embodiments, only one of the first groove 105 and the second groove 106 may be formed separately. For the structures and functions of the first groove 105 and the second groove 106, reference can be made to Embodiment 1, and the description thereof is omitted herein.

The effective resonant region includes a region where the first electrode 102, the piezoelectric layer 103, and the second electrode 104 overlap each other in a direction perpendicular to the surface of the piezoelectric stack structure.

Referring to FIG. 10, in some embodiments, after the BAW filter is formed, a first structural layer 13 is formed on the second electrode 104, and the first structural layer 13 is etched to form a first isolation groove 120a′. The first isolation groove 120a′ at least exposes the effective resonant region of the second electrode 104.

Before forming the first structural layer 13, the fabrication method further includes forming an etch stop layer (not shown) on the second electrode 104, and forming the first structural layer 13 on the etch stop layer. The first structural layer 13 is an oxide layer. For the materials and the functions of the oxide layer and the etch stop layer, reference can be made to the foregoing embodiments, which will not be repeated herein.

In some other embodiments, the first structural layer 13 may also be formed on the SAW filter. For detail description, reference can be made to FIGS. 2-6 and the descriptions thereof.

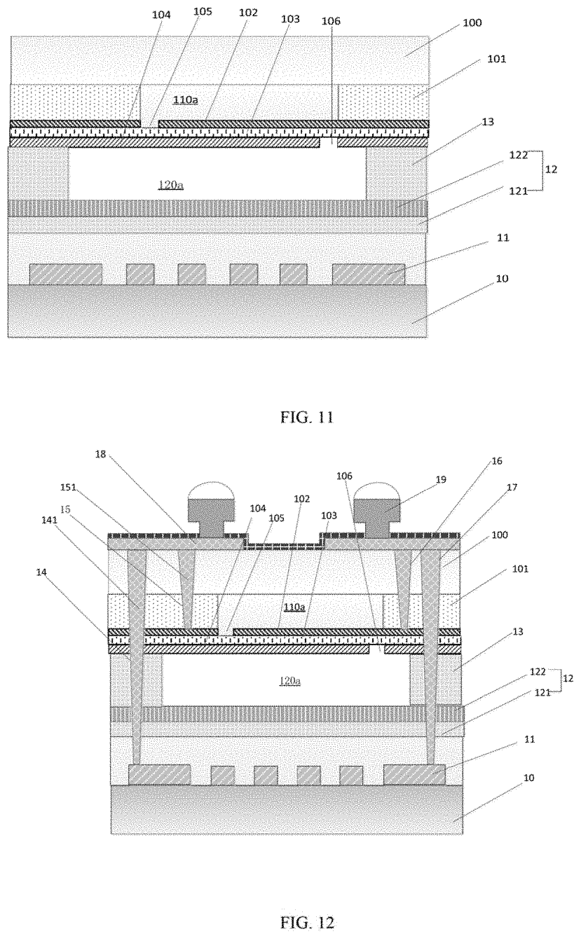

Referring to FIG. 11, in some embodiments, based on FIG. 6, the BAW filter is bonded to the SAW filter, such that the first isolation groove 120a′ is sandwiched between the SAW filter and the BAW filter to form the first cavity 120a.

In some other embodiments, based on FIG. 4, after the first structural layer 13 is formed on the BAW filter, the BAW filter is bonded to the SAW filter. The first structural layer 13 is bonded to the passivation layer 12 of SAW filter, that the first isolation groove 120a′ is sandwiched between the SAW filter and the BAW filter to form the first cavity 120a.

The effective resonance region of the piezoelectric stack structure and the interdigital transducer 11 of the SAW filter cover the first cavity 120a.

Through the bonding process, the BAW filter is bonded to the SAW filter and forms the first cavity 120a with the SAW filter. The effective resonance region of the piezoelectric stack structure and the interdigital transducer 11 of the SAW filter cover the first cavity 120a, such that functional regions of the SAW filter and the BAW filter share a cavity, which facilitates vertical integration, reduces the overall system cost, shrinks the package volume, achieving miniaturization, and substantially improves integration level. The embodiments of the present disclosure not only retain the advantages of high-frequency and low insertion loss of the BAW filter and simplify the fabrication process, but also reduce the production cost. The effective resonance region of the piezoelectric stack structure is located in the first cavity 120a. The upper and lower surfaces of the effective resonance region are completely exposed in the air, which effectively improves the quality factor of the BAW filter.

Further, at least one of the SAW filter and the BAW filter is a wafer, and the subsequent processes such as bonding process and electrical connection are completed on the wafer, which facilitates simultaneous production of different frequency-band filters on one wafer. Thus, the complexity of the fabrication process can be reduced, and the production can be substantially increased.

Referring to FIG. 12, after the BAW filter and the SAW filter are bonded, he fabrication method further includes forming a first electrical connection structure 14 and a fourth electrical connection structure 17 to electrically connect the SAW filter to an external circuit, and forming a second electrical connection structure 15 and a third electrical connection structure 16 to electrically connect the BAW filter to another external circuit.

The process for forming the first electrical connection structure 14 includes: forming a first interconnection hole (not shown) through an etching process, the first interconnection hole penetrating from one side of the supporting substrate 100 and extending to the interdigital transducer of the SAW filter, and forming a first conductive interconnection layer 141 in the first interconnection hole, the first conductive interconnection layer 141 covering an inner surface of the first interconnection hole. The process for forming the second electrical connection structure 15 includes forming a second interconnection hole (not shown) through the etching process, the second interconnection hole penetrating from one side of the supporting substrate 100 and extending to the outside of the effective resonance region of the piezoelectric stack structure on the first electrode 102, and forming a second conductive interconnection layer 151 in the second interconnection hole, the second conductive interconnection layer 151 covering an inner surface of the second interconnection hole.

After forming the first electrical connection structure 14 and the second electrical connection structure 15, an interconnection line 18 is formed on a surface of the supporting substrate 100. An insulating layer is formed on the interconnection line 18, and the insulating layer covers the interconnection line 18 and the surface of the supporting substrate 100. A conductive bump 19 is arranged on the surface of the supporting substrate 100 and is electrically connected to the interconnection line 18. The conductive bump 19 is electrically connected to the external circuits. The first conductive interconnection layer 141 and the second conductive interconnection layer 151 are electrically connected to the interconnection line 18.

In some embodiments, the first conductive interconnection layer 141 includes a first plug, and the second conductive interconnection layer 151 includes a second plug.

Specifically, one end of the first plug is connected to an input end of the interdigital transducer 11 for providing signal voltage to a transmitting transducer, and the other end is connected to the interconnection line 18. The interconnection line 18 is used to connect to an external circuit. One end of the second plug is connected to the first electrode 102 outside the effective resonance region, and is used to introduce an electrical signal into the second electrode 104 of the effective resonance region. The third electrical connection structure 16 is used to introduce another electrical signal into the effective resonance region. After the first electrode 102 and the second electrode 104 are energized, a pressure difference is generated on the upper and lower surfaces of the piezoelectric layer 103 to form a standing wave oscillation. The fourth electrical connection structure 17 is used to connect an output end of the interdigital transducer 11. The surface acoustic wave forming a sound at the input end propagates along the surface of the substrate to an interdigital electrode at the output end. Due to the pressure effect, an electric field changes due to mechanical vibrations, and an electrical signal is outputted at the output end. The third electrical connection structure 16 is formed in the same way as the second electrical connection structure 15, the fourth electrical connection structure 17 is formed in the same way as the first electrical connection structure 14, and the descriptions thereof will not be repeated here.

It should be noted that, the bonding process of bonding the SAW filter and the BAW filter also includes placing multiple SAW filters on the SAW filter wafer, and/or placing multiple BAW filters on the BAW filter wafer. After the bonding process is completed, the embodiments of the present disclosure also include separating and forming individual bonding pairs of the SAW filter and the BAW filter.

The beneficial effects of the method embodiments of the present disclosure includes the following. The first structural layer with the first cavity is formed between the SAW filter and the BAW filter. The effective resonance region of the piezoelectric stack structure of the BAW filter and the interdigital transducer of the SAW filter together cover the first cavity, which facilitates the vertical integration, reduces the package volume of the entire system, achieving the miniaturization, and substantially improves the integration level. The embodiments of the present disclosure not only retain the advantages of high-frequency and low insertion loss of the BAW filter and simplify the fabrication process, but also reduce the production cost. The effective resonance region of the piezoelectric stack structure is located in the first cavity 120a. The upper and lower surfaces of the effective resonance region are completely exposed in the air, which effectively improves the quality factor of the BAW filter.

Further, by forming the electrical connection structures with the BAW filter and the SAW filter to electrically connect to different external circuits respectively, mutual interferences of signals of the SAW filter and the BAW filter can be avoided, and the performance of the MEMS device can be improved.

Further, the effective resonance region of the BAW filter is defined by the first groove and the second groove. The first groove and the second groove respectively penetrate the first electrode and the second electrode, and the piezoelectric layer remains intact without being etched, which ensures the structural strength of the BAW filter and improves the yield of the BAW filter.

The beneficial effects of the fabrication methods of the present disclosure further include the following. Through the bonding process, the BAW filter is bonded to the SAW filter and forms the first cavity with the SAW filter. The effective resonance region of the piezoelectric stack structure and the interdigital transducer of the SAW filter together cover the first cavity, such that functional regions of the SAW filter and the BAW filter share a cavity, which facilitates the vertical integration, reduces the overall system cost, shrinks the package volume, achieving the miniaturization, and substantially improves the integration level. The embodiments of the present disclosure not only retain the advantages of high-frequency and low insertion loss of the BAW filter and simplify the fabrication process, but also reduce the production cost. The effective resonance region of the piezoelectric stack structure is located in the first cavity. The upper and lower surfaces of the effective resonance region are completely exposed in the air, which effectively improves the quality factor of the BAW filter

Further, at least one of the SAW filter and the BAW filter is a wafer, and the subsequent processes such as bonding process and electrical connection are completed on the wafer, which facilitates simultaneous production of different frequency-band filters on one wafer. Thus, the complexity of the fabrication process can be reduced, and the production can be substantially increased.

Further, the first structural layer is the photolithographically curable organic film, which relieves the bonding stress of the SAW filter and the BAW filter and provides high bonding reliability of the SAW filter and the BAW filter. The first cavity is obtained by etching, thereby minimizing damages to the surface of the filters.

Further, the passivation layer is provided on the SAW filter, which provides the dustproof, waterproof and anticorrosion functions for the SAW filter.

It should be noted that each embodiment in this specification is described in a related manner, the same and similar parts of each embodiment can be referred to each other. Each embodiment focuses on the differences from other embodiments.

The over description is only descriptions of exemplary embodiments of the present disclosure, and does not limit the scope of the present disclosure. Any changes and modifications made by those of ordinary skill in the field of the present disclosure based on the over disclosures shall fall within the protection scope of the claims.

What is claimed is:

1. A microelectromechanical systems (M EMS) device, comprising:
a surface acoustic wave (SAW) filter including an interdigital transducer;
a first structural layer disposed over the SAW filter; and
a bulk acoustic wave (BAW) filter disposed over the first structural layer;
wherein:
the BAW filter includes a supporting substrate, an acoustic reflective structure disposed over the supporting substrate, and a piezoelectric stack structure disposed over the acoustic reflective structure;
the piezoelectric stack structure includes a first electrode, a piezoelectric layer, and a second electrode; and
the first structural layer includes a first cavity covered by an effective resonance region of the piezoelectric stack structure and the interdigital transducer of the SAW filter.

2. The MEMS device according to claim 1, wherein:
the first cavity penetrates through the first structural layer.

3. The MEMS device according to claim 1, wherein:
the first structural layer includes a photolithographically curable organic film or an oxide layer.

4. The MEMS device according to claim 1, wherein:
a thickness of the first structural layer ranges between 5 μm and 50 μm.

5. The MEMS device according to claim 1, wherein:
a passivation layer is disposed between the SAW filter and the first structural layer;
the passivation layer includes the oxide layer and an etch stop layer;
the oxide layer is disposed on an upper surface of the SAW filter; and
the etch stop layer is disposed on the oxide layer.

6. The MEMS device according to claim 1, wherein:
the acoustic reflective structure includes a support layer disposed over the supporting substrate, and a second cavity of the SAW filter enclosed by the supporting substrate, the support layer, and the piezoelectric stack structure.

7. The MEMS device according to claim 1, wherein:
the SAW filter is electrically connected to an external circuit through a first electrical connection structure and a fourth electrical connection structure; and
the BAW filter is electrically connected to another external circuit through a second electrical connection structure and a third electrical connection structure.

8. The MEMS device according to claim 7, wherein:
the first electrical connection structure includes a first interconnection hole and a first conductive interconnection layer disposed in the first interconnection hole, the first interconnection hole penetrating from one side of the supporting substrate and extending to the interdigital transducer of the SAW filter; and
the second electrical connection structure includes a second interconnection hole and a second conductive interconnection layer disposed in the second interconnection hole, the second interconnection hole penetrating from one side of the supporting substrate and extending to the first electrode outside the effective resonance region of the piezoelectric stack structure.

9. The MEMS device according to claim 8, wherein:
an interconnection line is formed on the supporting substrate;
the first conductive interconnection layer includes a first plug, and the second conductive interconnection layer includes a second plug; and
the first plug and the second plug are electrically connected to the interconnection line.

10. The MEMS device according to claim 6, wherein:
a first groove is formed at a bottom of the second cavity penetrating the first electrode;
a second groove is formed at a position opposite to the first groove penetrating the second electrode; and
two junctions of orthogonal projections of the first groove and the second groove on the supporting substrate meet with each other or are separated by a gap.

11. The MEMS device according to claim 1, wherein:
the acoustic reflective structure includes a Bragg reflective layer.

12. A method for fabricating a microelectromechanical systems (MEMS) device, comprising:
providing a surface acoustic wave (SAW) filter including an interdigital transducer;
providing a bulk acoustic wave (BAW) filter including a supporting substrate, a support layer disposed over the supporting substrate, and a piezoelectric stack structure configured to enclose a second cavity with the support substrate and the support layer; and
bonding the BAW filter to the SAW filter through a first structural layer to form a first cavity with the SAW filter;
wherein an effective resonance region of the piezoelectric stack structure and the interdigital transducer of the SAW filter together cover the first cavity.

13. The fabrication method according to claim 12, further comprising:
in a bonding process, placing multiple SAW filters on a SAW filter wafer, and/or placing multiple BAW filters on a BAW filter wafer; and
after the bonding process is completed, separating and forming individual bonding pairs of the SAW filter and the BAW filter.

14. The fabrication method according to claim 12, wherein:
forming the first cavity includes:
providing the SAW filter;
forming the first structural layer on the SAW filter;
etching the first structural layer to form a first isolation groove at a position opposite to the interdigital transducer;
providing the BAW filter; and
bonding the BAW filter to the first structural layer, such that the first isolation groove is disposed between the SAW filter and the BAW filter to form the first cavity; or
forming the first cavity includes:
providing the SAW filter;
providing the BAW filter and forming the first structural layer on the piezoelectric stack structure;
etching the first structural layer to form the first isolation groove; and
bonding the first structural layer to SAW filter, such that the first isolation groove is disposed between the SAW filter and the BAW filter to form the first cavity.

15. The fabrication method according to claim 12, wherein:
forming a passivation layer between the SAW filter and the first structural layer.

16. The fabrication method according to claim 15, wherein:
the passivation layer includes an oxide layer and an etch stop layer, the oxide layer is formed on the SAW filter, and the etch stop layer is formed on the oxide layer.

17. The fabrication method according to claim 12, wherein forming the BAW filter includes:
providing a temporary substrate;
forming the piezoelectric stack structure on the temporary substrate, the piezoelectric stack structure including a second electrode, a piezoelectric layer, and a first electrode that are formed sequentially upward over the temporary substrate;
forming a support material layer covering the piezoelectric stack structure;
performing patterning process on the support material layer to form the second cavity and the support layer, the second cavity penetrating through the support layer;
bonding the supporting substrate to the support layer, the supporting substrate covering the second cavity; and
removing the temporary substrate.

18. The fabrication method according to claim 17, further comprising after the BAW filter and the SAW filter are bonded:
forming a first electrical connection structure to electrically connect the SAW to an external circuit; and
forming a second electrical connection structure to electrically connect the BAW filter to another external circuit;
wherein forming the first electrical connection structure includes:
forming a first interconnection hole through an etching process, the first interconnection hole penetrating from one side of the supporting substrate and extending to the interdigital transducer of the SAW filter; and
forming a first conductive interconnection layer in the first interconnection hole, the first conductive interconnection layer covering an inner surface of the first interconnection hole; and
forming the second electrical connection structure includes:
forming a second interconnection hole through the etching process, the second interconnection hole penetrating from one side of the supporting substrate and extending to the first electrode outside the effective resonance region of the piezoelectric stack structure; and
forming a second conductive interconnection layer in the second interconnection hole, the second conductive interconnection layer covering an inner surface of the second interconnection hole.

19. The fabrication method according to claim 18, further comprising after the first electrical connection structure and the second electrical connection structure are formed:
forming an interconnection line over the supporting substrate;
wherein:
the interconnection line is electrically connected to the external circuits;
the first conductive interconnection layer and the second conductive interconnection layer are electrically connected to the interconnection line; and
the first conductive interconnection layer includes a first plug, and the second conductive interconnection layer includes a second plug.

20. The fabrication method according to claim 12, wherein:
material of the first structural layer includes any one of a photolithographic organic curable film, silicon oxide, silicon oxynitride, and silicon nitride.
